(19) United States
(12) Patent Application Publication
(10) Pub. No.: US 2010/0037791 A1
(43) Pub. Date: Feb. 18, 2010

(54) METHOD OF MAKING A LITHOGRAPHIC PRINTING PLATE

(75) Inventors: Hieronymus Andriessen, Beerse (BE); Guido Hauquier, Nijlen (BE)

Correspondence Address: AGFA;c/o KEATING & BENNETT, LLP, 1800 Alexander Bell Drive, SUITE 200, Reston, VA, 20191, US

(73) Assignee: AGFA GRAPHICS NV, Mortsel (BE)

(21) Appl. No.: 12/530,656

(22) PCT Filed: Mar. 6, 2008
(86) PCT No.: PCT/EP08/52722

§ 371 Date: Sep. 10, 2009

Related U.S. Application Data
(60) Provisional application No. 60/908,476, filed on Mar. 28, 2007.

(30) Foreign Application Priority Data
Mar. 27, 2007 (EP) 07104991.0

(51) Int. Cl. B41F 1/18; G03F 7/00; B41N 3/00

(52) U.S. Cl. 101/450.1; 430/302; 101/465

(57) ABSTRACT

A method for making a lithographic printing plate including the steps of providing a lithographic printing plate precursor including a heat sensitive image-recording layer, the image-recording layer including hydrophobic thermoplastic particles; image-wise exposing the precursor to infrared radiation having an energy density of 190 mJ/cm2 or less; mounting the exposed precursor on a printing press; developing the mounted precursor by supplying ink and/or fountain; and baking the plate by keeping the plate at a temperature above the glass transition temperature of the thermoplastic particles during a period between 5 seconds and 2 minutes.

### CROSS-REFERENCE TO RELATED APPLICATIONS

This application is a 371 National Stage Application of PCT/EP2008/052722, filed Mar. 6, 2008. This application claims the benefit of U.S. Provisional Application No. 60/908,476, filed Mar. 28, 2007, which is incorporated by reference herein in its entirety. In addition, this application claims the benefit of European Application No. 07104991.0, filed Mar. 27, 2007, which is also incorporated by reference herein in its entirety.

### BACKGROUND OF THE INVENTION

1. Field of the Invention

The present invention relates to a method for making a lithographic printing plate.

2. Description of the Related Art

Lithographic printing presses use a so-called printing master such as a printing plate which is mounted on a cylinder of the printing press. The master carries a lithographic image on its surface and a print is obtained by applying ink to the image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e., ink-accepting, water-repelling) areas as well as hydrophilic (or oleophobic, i.e., water-accepting, ink-repelling) areas. In so-called driographic printing, the lithographic image consists of ink-accepting and ink-abhesive (ink-repelling) areas and during driographic printing, only ink is supplied to the master.

Printing masters are generally obtained by the image-wise exposure and processing of an imaging material called a plate precursor. In addition to the well-known photosensitive, so-called pre-sensitized plates, which are suitable for UV contact exposure through a film mask, also heat-sensitive printing plate precursors have become very popular in the late 1990s. Such thermal materials offer the advantage of daylight stability and are especially used in the so-called computer-to-plate method wherein the plate precursor is directly exposed, i.e., without the use of a film mask. The material is exposed to heat or to infrared radiation and the generated heat triggers a (physico-)chemical process, such as ablation, polymerization, insolubilization by crosslinking of a polymer, heat-induced solubilization, or by particle coagulation of a thermoplastic polymer latex.

Although some of these thermal processes enable plate making without wet processing, the most popular thermal plates form an image by a heat-induced solubility difference in an alkaline developer between exposed and non-exposed areas of the coating. The coating typically includes an oleophilic binder, e.g., a phenolic resin, of which the rate of dissolution in the developer is either reduced (negative working) or increased (positive working) by the image-wise exposure. During processing, the solubility differential leads to the removal of the non-image (non-printing) areas of the coating, thereby revealing the hydrophilic support, while the image (printing) areas of the coating remain on the support. Negative working preferred embodiments of such thermal materials often require a pre-heat step between exposure and development as described in, e.g., EP-A 625 728.

Negative working plate precursors which do not require a pre-heat step may contain an image-recording layer that works by heat-induced particle coalescence of a thermoplastic polymer latex, as described in, e.g., EP-A's 770 494, 770 495, 770 496 and 770 497. These patents disclose a method for making a lithographic printing plate including the steps of (1) image-wise exposing a plate precursor having a heat-sensitive image-recording layer to infrared radiation, wherein the image-recording layer includes hydrophobic thermoplastic polymer particles, sometimes also referred to as latex particles, which are dispersed in a hydrophilic binder, and (2) developing the image-wise exposed element by applying water or by mounting the plate on the plate cylinder of a press and then supplying fountain solution and/or ink. During the development step, the unexposed areas of the image-recording layer are removed from the support, whereas the latex particles in the exposed areas have coalesced to form a hydrophobic phase which is not removed in the development step. In EP-A 1 342 568 a similar plate precursor is developed with a gum solution and in EP-A's 1 614 538, 1 614 539 and 1 614 540 development is achieved by means of an alkaline solution.

It is known in the art that lithographic plates, obtained after exposure, development and optional gumming, can be heat-treated in a so-called post-baking step in order to increase the run length of the plate on the press. A typical post-baking is carried out by heating the plate in an oven at a high temperature, e.g., of about 250° C.

EP-A 1 506 854 describes a method for post-baking various plates, including plates that work by heat-induced latex coalescence, in a short time of 1 minute or less by means of an infrared radiation source.

In the unpublished EP-A 05 108 920.9 (filed 2005-09-27) a method is disclosed wherein after development in a processing unit including a gumming solution or an alkaline solution, a mild post-baking step is performed.

A problem associated with plate precursors that work according to the mechanism of heat-induced latex coalescence, especially when development is carried out on-press by applying ink and/or fountain solution, is that it is difficult to obtain both a high sensitivity and a high run length. The energy density required to obtain a sufficient degree of latex coalescence and of adherence of the exposed areas to the support is often higher than 250 mJ/cm². As a result, in plate-setters or printing presses equipped with low power exposure devices, such as semiconductor infrared laser diodes, long exposure times are needed. This results in a low throughput, i.e., number of precursors that can be exposed in a given time interval.

A higher sensitivity and run length can be obtained, e.g., by providing an image-recording layer that has a better resistance towards the developer in the unexposed state, so that a low energy density suffices to render the image-recording layer completely resistant to the developer. However, such an image-recording layer is difficult to remove during on-press development resulting in toning (ink acceptance in the non-image areas). Removal of the unexposed areas of the image-recording layer is more difficult during on-press development compared to conventional development because a typical fountain solution used to develop the precursors is much less aggressive compared to an alkaline developing solution. Such toning will be enhanced when the plate is baked after development.

Another way to provide a higher sensitivity can be achieved by using latex particles that are only weakly stabilized so that they coalesce readily upon exposure. However, such latex particles tend to remain on the support also in the unexposed state and again, an insufficient clean-out (removal of the coating during on-press development) is obtained, resulting in toning.

On the other hand, well-stabilized latex particles are easily removed from the support and show no clean-out problems but they require more energy to coalesce and thus a low sensitivity plate is obtained.

### SUMMARY OF THE INVENTION

Preferred embodiments of the present invention provide a negative-working lithographic printing plate precursor that works by heat-induced coalescence of thermoplastic polymer particles, which enables both (i) a short exposure time and (ii) a very good run length.

A preferred embodiment of the present invention is realized by a method described below, having the specific features that the precursor is exposed at an energy density of 190 mJ/cm² or less, and that the precursor is, after development on-press, subjected to a mild post-baking step, more particularly to a post-baking step between 5 seconds and 2 minutes.

It was surprisingly found that an energy density of 190 mJ/cm² or less, which is typically too low for providing a good adherence of the exposed areas to the support, nevertheless is sufficient to render the exposed areas resistant to the development step. Without prejudice to the scope of our claims, it seems that the mild post-baking step compensates for the underexposure, as explained hereafter. The energy density of 190 mJ/cm² seems to be sufficient to provide enough differentiation between exposed and unexposed areas to obtain a high-quality lithographic image after development, i.e., a complete clean-out of the unexposed areas without substantially affecting the exposed areas. However, the mechanical and chemical resistance of the (underexposed) lithographic image is insufficient to provide an acceptable run length of the plate during printing According to a preferred embodiment of the present invention, that problem is solved by the mild post-baking step; i.e., a post baking step between 5 seconds and 2 minutes.

As an additional benefit, the plate-making time is reduced by the combination of a short exposure time, on-press processing and a short post-baking step. Furthermore, the short post-baking step, especially when the post-baking is performed on-press, eliminates the risk of distortion of the support which is often observed after a conventional post-baking step. In addition, no separate processing unit and dedicated chemicals to develop the exposed precursors are needed due to the on-press development in the method of the present invention.

Other features, elements, steps, characteristics and advantages of the present invention will become more apparent from the following detailed description of preferred embodiments of the present invention with reference to the attached drawing.

### BRIEF DESCRIPTION OF THE DRAWINGS

FIG. 1 shows the rendering of a 1% dot patch (200 lpi) generated with the AGFA BALANCED SCREENING software (Trademark of Agfa Graphics NV) on print 5,000 and print 50,000, produced with the comparative printing plates PP-01 and PP-02 and the inventive printing plate PP-03.

### DETAILED DESCRIPTION OF THE PREFERRED EMBODIMENTS

A method for making a lithographic printing plate according to one preferred embodiment of the present invention includes the steps of:

providing a lithographic printing plate precursor including a heat sensitive image-recording layer, the image-recording layer including hydrophobic thermoplastic particles;

image-wise exposing the precursor to infrared radiation having an energy density of 190 mJ/cm² or less;

mounting the exposed precursor on a printing press;

developing the mounted precursor by supplying ink and/or fountain solution; and

baking the plate by keeping the plate at a temperature above the glass transition temperature of the thermoplastic particles during a period between 5 seconds and 2 minutes.

Optionally, after development on-press and before baking the plate, the ink is removed from the plate. After baking the plate and before printing, the baked plate may be cleaned.

A method for making a lithographic printing plate according to another preferred embodiment of the present invention includes the steps of:

mounting a lithographic printing plate precursor on a printing press, the precursor including a heat sensitive image-recording layer, the image-recording layer including hydrophobic thermoplastic particles;

image-wise exposing the precursor to infrared radiation having an energy density of 190 mJ/cm³ or less;

developing the mounted precursor by supplying ink and/or fountain solution; and

baking the plate by keeping the plate at a temperature above the glass transition temperature of the thermoplastic particles during a period between 5 seconds and 2 minutes.

As described above, after development on-press and before baking the plate, the ink may be removed from the plate. After baking the plate and before printing the baked plate may be cleaned.

### Lithographic Printing Plate Precursor

The heat-sensitive printing plate precursor includes a support and a coating. The coating may include one or more layer(s). The layer of the coating including the hydrophobic thermoplastic particles is referred to as the image-recording layer.

### Hydrophobic Thermoplastic Particles

The hydrophobic thermoplastic particles preferably have an average particle diameter from 15 nm to 75 nm, more preferably from 25 to 55 nm, most preferably from 35 nm to 45 nm. The average particle diameter referred to in the claims and the description of this application is meant to be the average particle diameter measured by Photon Correlation Spectrometry, also known as Quasi-Elastic or Dynamic Light-Scattering, unless otherwise specified. The measurements were performed according the ISO 13321 procedure (first edition, 1996-07-01) with a Brookhaven BI-90 analyzer, commercially available from Brookhaven Instrument Company, Holtsville, N.Y., USA.

The amount of hydrophobic thermoplastic polymer particles is preferably at least 50, more preferably at least 60, most preferably at least 70 percent by weight relative to the weight of all the ingredients in the image-recording layer.

The hydrophobic thermoplastic polymer particles which are present in the coating may be selected from polyethylene, polyvinylchloride, polymethyl(meth)acrylate, polyethyl(meth)acrylate, polyvinylidene chloride, poly(meth)acrylonitrile, polyvinylcarbazole, polystyrene or copolymers thereof.

According to a preferred embodiment, the thermoplastic polymer particles include polystyrene or derivatives thereof, mixtures including polystyrene and poly(meth)acrylonitrile or derivatives thereof, or copolymers including styrene and (meth)acrylonitrile or derivatives thereof. The latter copolymers may include at least 30% by weight of polystyrene, more preferably at least 50% by weight of polystyrene. In order to obtain sufficient resistivity towards organic chemicals such as hydrocarbons used in, e.g., plate cleaners, the thermoplastic polymer particles preferably include at least 5% by weight, more preferably at least 30% by weight, of nitrogen containing units, such as (meth)acrylonitrile, as described in EP-A 1 219 416. According to the most preferred embodiment, the thermoplastic polymer particles consist essentially of styrene and acrylonitrile units in a weight ratio between 1:1 and 5:1 styrene:acrylonitrile, e.g., in a 2:1 ratio.

The thermoplastic polymer particles include preferably a polymer or co-polymer having a weight average molecular weight ranging from 5,000 to 1,000,000 g/mol.

The hydrophobic thermoplastic polymer particles can be prepared by addition polymerization or by condensation polymerization. They are preferably applied onto the lithographic base in the form of a dispersion in an aqueous coating liquid. These water based dispersions can be prepared by polymerization in a water-based system, e.g., by free-radical emulsion polymerization as described in U.S. Pat. No. 3,476,937 or EP-A 1 217 010 or by means of dispersing techniques of the water-insoluble polymers into water. Another method for preparing an aqueous dispersion of the thermoplastic polymer particles includes (1) dissolving the hydrophobic thermoplastic polymer in an organic water immiscible solvent, (2) dispersing the thus obtained solution in water or in an aqueous medium and (3) removing the organic solvent by evaporation.

Emulsion polymerization is typically carried out through controlled addition of several components, i.e., vinyl monomers, surfactants (dispersion aids), initiators and optionally other components such as buffers or protective colloids, to a continuous medium, usually water. The resulting polymer of the emulsion polymerization is a dispersion of discrete particles in water. The surfactants or dispersion aids which are present in the reaction medium have a multiple role in the emulsion polymerization: (1) they reduce the interfacial tension between the monomers and the aqueous phase, (2) they provide reaction sites through micelle formation in which the polymerization occurs and (3) they stabilize the growing polymer particles and ultimately the latex emulsion. The surfactants are adsorbed at the water/polymer interface and thereby prevent coagulation of the fine polymer particles. Non-ionic, cationic and anionic surfactants may be used in emulsion polymerization. Preferably non-ionic and anionic surfactants are used. Most preferably the hydrophobic thermoplastic particles are stabilized with an anionic dispersion aid. Specific examples of suitable anionic dispersion aids include sodium lauryl sulphate, sodium lauryl ether sulphate, sodium dodecyl sulphate, sodium dodecyl benzene sulphonate and sodium lauryl phosphate; suitable non-ionic dispersion aids are for example ethoxylated lauryl alcohol and ethoxylated octyl- or nonyl phenol.

### Binder

The image-recording layer may further include a hydrophilic binder. Examples of suitable hydrophilic binders are homopolymers and copolymers of vinyl alcohol, (meth)acrylamide, methylol (meth)acrylamide, (meth)acrylic acid, hydroxyethyl(meth)acrylate, and maleic anhydride/vinylmethylether copolymers, copolymers of (meth)acrylic acid or vinylalcohol with styrene sulphonic acid.

Preferably the hydrophilic binder includes polyvinylalcohol or polyacrylic acid.

The amount of hydrophilic binder may be between 2.5 and 50, preferably between 5 and 25, more preferably between 10 and 15 percent by weight relative to the total weight of all ingredients of the image-recording layer.

The amount of the hydrophobic thermoplastic polymer particles relative to the amount of the binder is preferably between 2 and 15, more preferably between 4 and 10, most preferably between 5 and 7.5.

### Infrared Radiation Absorbing Compound

The coating includes a compound which absorbs infrared radiation and converts the absorbed energy into heat. The amount of the infrared radiation absorbing compound in the coating is preferably between 0.5 and 25.0 percent by weight, more preferably between 0.5 and 20.0 percent by weight.

The infrared radiation absorbing compound may be present in the image-recording layer, or a layer adjacent to the image-recording layer. The layer adjacent to the image-recording layer may be undercoat layer, i.e., between the image-recording layer and the support, or an overcoat, i.e., on top of the image-recording layer.

When the infrared radiation absorbing compound is present in the image-recording layer, its amount is preferably at least 6 percent by weight, more preferably at least 8 percent by weight relative to the weight of all the components of the image-recording layer.

The infrared radiation absorbing compounds may be pigments such as, e.g., carbon black but are preferably dyes, hereinafter referred to as IR-dye, such as cyanine, merocyanine, indoaniline, oxonol, pyrilium and squarilium dyes. Examples of suitable infrared radiation absorbing compounds are described in, e.g., EP-As 823 327, 978 376, 1 029 667, 1 053 868, 1 093 934 and WO's 97/39894 and 00/29214.

Highly preferred IR-dyes are described in EP 1 614 541 (paragraph [0061] to [0069]), EP 1 736 312 (paragraph [0014] to [0026]) and WO 2006 136 543 (pages 6 to 35). These IR-dyes are particularly preferred for on-press development since these dyes give rise to a print-out image after exposure to IR-radiation, prior to development on-press.

To optimize the clean-out of the lithographic printing plate precursor, especially when using hydrophobic thermoplastic particles having a particle size of from 25 to 55 nm, the amount of IR-dye is preferably as described in the unpublished EP-A 06 114 473.9 (filed 2006-05-24).

To even further optimize the clean-out of the lithographic printing plate precursor, especially when using hydrophobic thermoplastic particles having a particle size of from 25 to 55 nm, an additional dye, the dye not absorbing infrared radiation, may be present in the image-recording layer as described in EP-A 06 122 415.0 and 06 122 423.4 (both filed 2006-10-17).

### Stabilizer

The coating, more preferably the image-recording layer, may further include a light stabilizer or anti-oxidant to prevent, e.g., degradation of the IR-dye upon exposure of the precursor to daylight. The light stabilizer or anti-oxidant is preferably selected from the group consisting of steric hindered phenoles, hindered amine light stabilizers (HALS) and their N-oxyl radicals, tocopheroles, hydroxyl amine derivatives, such as hydroxamic acids and substituted hydroxylamines, hydrazides, thioethers, trivalent organophosphor compounds such as phosphites and reductones. In a particularly preferred embodiment, the light stabilizer is a reductone. Most preferably, the light stabilizer is an ascorbic or isoascorbic acid derivative according to Formula I:

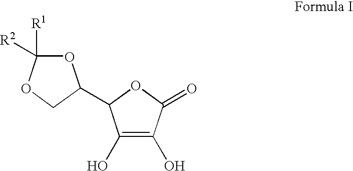

wherein R¹ and R² independently represent a hydrogen atom, an optionally substituted alkyl group, an optionally substituted alkenyl group, an optionally substituted alkynyl group, an optionally substituted aralkyl group, an optionally substituted alkaryl group, an optionally substituted heterocyclic group or an optionally substituted heteroaryl group. R¹ and R² may represent the necessary atoms to form a carbocyclic or a heterocyclic ring.

Typical examples of light stabilizers according to Formula I are given below:

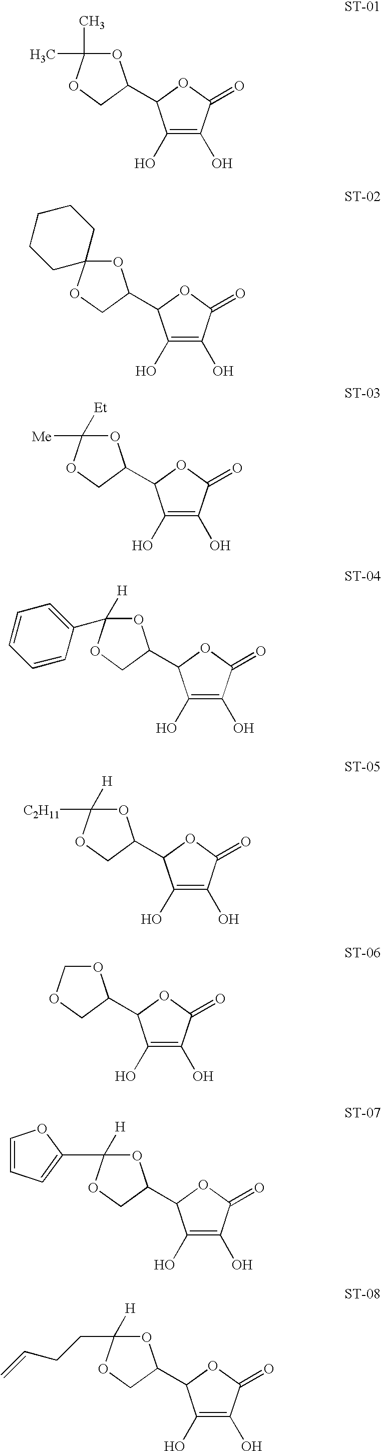

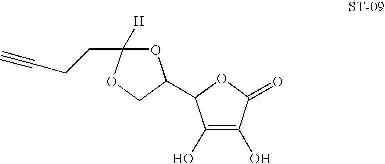

In a most preferred embodiment, both R¹ and R² represent a C-1 to C-5 alkyl group. The alkyl group referred to means all variants possible for each number of carbon atoms in the alkyl group, i.e., for three carbon atoms: n-propyl and i-propyl; for four carbon atoms: n-pentyl, 1,1-dimethylpropyl, 2,2-dimethylpropyl and 2-methylbutyl; etc.

To prepare the products according to Formula I, the synthesis methods described in, e.g., Bioorganic & Medicinal chemistry Letters, 16, pages 5313-5316, 2006; Tetrahedron Letters, 45, pages 5395-5398, 2004; Bioorganic & Medicinal chemistry Letters, 11, pages 2301-2304, 2001; Journal of Medicinal Chemistry, 35, pages 1618-1623, 1992;

The stabilizer according to Formula I is preferably added in an amount of from 1 to 100 mg/m², more preferably from 2 to 50 mg/m², most preferably from 5 to 25 mg/m².

### Other Ingredients

Optionally, the coating may further contain additional ingredients. These ingredients may be present in the image-recording layer or in an optional other layer. For example, additional binders, polymer particles such as matting agents and spacers, surfactants such as perfluoro-surfactants, silicon or titanium dioxide particles, development inhibitors, development accelerators, and metal complexing agents are well-known components of lithographic coatings.

Preferably the image-recording layer includes an organic compound, characterized in that the organic compound includes at least one phosphonic acid group or at least one phosphoric acid group or a salt thereof, as described in the unpublished PCT/EP2006/061296 (filed 2006, Apr. 4). In a particularly preferred embodiment the image-recording layer includes an organic compound as represented by Formula II:

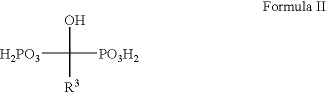

or a salt thereof and wherein R³ independently represent hydrogen, an optionally substituted straight, branched, cyclic or heterocyclic alkyl group or an optionally substituted aryl or (hetero)aryl group.

Compounds according to Formula II may be present in the image-recording layer in an amount between 0.05 and 15, preferably between 0.5 and 10, more preferably between 1 and 5 percent by weight relative to the total weight of the ingredients of the image-recording layer.

The coating may be applied on the support by any coating technique known in the art. After applying the coating, the applied layer(s) are dried as commonly known in the art. While drying the coating, in particular the image-recording layer, it is preferred to keep the temperature, measured as the wet coating temperature, below 45° C., more preferably below 40° C., most preferably below 35° C. and to keep the temperature, measured as the dry coating temperature, below 90° C., more preferably below 60° C.

### Optional Layers of the Coating

To protect the surface of the coating, in particular from mechanical damage, a protective layer may optionally be applied on top of the image-recording layer. The protective layer generally includes at least one water-soluble polymeric binder, such as polyvinyl alcohol, polyvinylpyrrolidone, partially hydrolyzed polyvinyl acetates, gelatin, carbohydrates or hydroxyethylcellulose. The protective layer may contain small amounts, i.e., less than 5 percent by weight, of organic solvents. The thickness of the protective layer is not particularly limited but preferably is up to 5.0 μm, more preferably from 0.05 to 3.0 μm, particularly preferably from 0.10 to 1.0 μm.

The coating may further contain other additional layer(s) such as for example an adhesion-improving layer located between the image-recording layer and the support.

### Support

The support of the lithographic printing plate precursor has a hydrophilic surface or is provided with a hydrophilic layer. The support may be a sheet-like material such as a plate or it may be a cylindrical element such as a sleeve which can be slid around a print cylinder of a printing press.

In one preferred embodiment of the invention the support is a metal support such as aluminum or stainless steel. The support can also be a laminate including an aluminum foil and a plastic layer, e.g., polyester film. A particularly preferred lithographic support is an aluminum support. Any known and widely used aluminum materials can be used. The aluminum support has a thickness of about 0.1-0.6 mm. However, this thickness can be changed appropriately depending on the size of the printing plate used and the plate-setters on which the printing plate precursors are exposed.

To optimize the lithographic properties, the aluminum support is subjected to several treatments well known in the art such as for example: degrease, surface roughening, etching, anodization, sealing, surface treatment. In between such treatments, a neutralization treatment is often carried out. A detailed description of these treatments can be found in, e.g., EP-As 835 764, 1 564 020 and 1 614 538.

A preferred aluminum substrate, characterized by an arithmetical mean center-line roughness Ra less than 0.45μ is described in EP 1 356 926.

Optimizing the pore diameter and distribution thereof of the grained and anodized aluminum surface may enhance the press life of the printing plate and may improve the toning behaviour. An optimal ratio between pore diameter of the surface of the aluminum support and the average particle diameter of the hydrophobic thermoplastic particles may enhance the press run length of the plate and may improve the toning behaviour of the prints. This ratio of the average pore diameter of the surface of the aluminum support to the average particle diameter of the thermoplastic particles present in the image-recording layer of the coating, preferably ranges from 0.1:1 to 1.0:1, more preferably from 0.3:1 to 0.8:1.

Alternative supports for the plate precursor can also be used, such as amorphous metallic alloys (metallic glasses). Such amorphous metallic alloys can be used as such or joined with other non-amorphous metals such as aluminum. Examples of amorphous metallic alloys are described in U.S. Pat. No. 5,288,344, U.S. Pat. No. 5,368,659, U.S. Pat. No. 5,618,359, U.S. Pat. No. 5,735,975, U.S. Pat. No. 5,250,124, U.S. Pat. No. 5,032,196, U.S. Pat. No. 6,325,868, and U.S. Pat. No. 6,818,078. The following references describe the science of amorphous metals in much more detail and are incorporated as references: Introduction to the Theory of Amorphous Metals, N. P. Kovalenko et al. (2001); Atomic Ordering in Liquid and Amorphous Metals, S. I. Popel, et al; Physics of Amorphous Metals, N. P. Kovalenko et al (2001).

According to another preferred embodiment, the support can also be a flexible support, which is provided with a hydrophilic layer. The flexible support is, e.g., paper, plastic film, thin aluminum or a laminate thereof. Preferred examples of plastic film are poly-ethylene terephthalate film, polyethylene naphthalate film, cellulose acetate film, polystyrene film, polycarbonate film, etc. The plastic film support may be opaque or transparent. Particular examples of suitable hydrophilic layers that may be supplied to a flexible support for use in accordance with the present invention are disclosed in EP-A 601 240, GB 1 419 512, FR 2 300 354, U.S. Pat. No. 3,971,660, U.S. Pat. No. 4,284,705, EP 1 614 538, EP 1 564 020 and US 2006/0019196.

### Exposure

The printing plate precursor is image-wise exposed with infrared radiation, preferably near infrared radiation. The infrared radiation is converted into heat by an infrared absorbing compound as discussed above. The heat-sensitive lithographic printing plate precursor of the present invention is preferably not sensitive to visible light. Most preferably, the coating is not sensitive to ambient daylight, i.e., visible (400-750 nm) and near UV light (300-400 nm) at an intensity and exposure time corresponding to normal working conditions so that the material can be handled without the need for a safe light environment.

The printing plate precursors of the present invention can be exposed to infrared radiation by means of, e.g., LEDs or an infrared laser. Preferably lasers, emitting near infrared radiation having a wavelength in the range from about 700 to about 1500 nm, e.g., a semiconductor laser diode, a Nd:YAG or a Nd:YLF laser, are used. Most preferably, a laser emitting in the range between 780 and 830 nm is used. The required laser power depends on the sensitivity of the image-recording layer, the pixel dwell time of the laser beam, which is determined by the spot diameter (typical value of modern plate-setters at 1/e² of maximum intensity: 10-25 μm) and the scan speed, and the resolution of the exposure apparatus (i.e., the number of addressable pixels per unit of linear distance, often expressed in dots per inch or dpi; typical value: 1000-4000 dpi).

In the method for preparing a lithographic printing plate according to the present invention the image-wise exposure is carried out with infrared radiation having an energy density, measured at the surface of the precursor, of 190 mJ/cm² or less, preferably of 170 mJ/cm² or less, more preferably of 150 mJ/cm² or less, most preferably of 130 mJ/cm² or less.

The image-wise exposure is performed off-press or on-press.

In the off-press exposure preferred embodiment, the exposure is performed in a plate-setter. After the exposure in the plate-setter, the thus obtained exposed precursor is mounted on a printing press to perform the subsequent steps of the method. Two types of laser-exposure apparatuses are commonly used: internal (ITD) and external drum (XTD) plate-setters. ITD plate-setters for thermal plates are typically characterized by a very high scan speed up to 1500 m/sec and may require a laser power of several Watts. The Agfa GALILEO T (trademark of Agfa Graphics NV) is a typical example of a plate-setter using the ITD-technology. XTD plate-setters for thermal plates having a typical laser power from about 20 mW to about 500 mW operate at a lower scan speed, e.g., from 0.1 to 20 m/sec. The Agfa XCALIBUR, ACCENTO and AVALON plate-setter families (trademarks of Agfa Graphics NV) make use of the XTD-technology.

According to another preferred embodiment of the present invention the image-wise exposure is performed on-press. According to this preferred embodiment, the precursor is first mounted on a printing press, wherein an exposure unit is incorporated. In this preferred embodiment the print cylinder constitutes the drum component of the exposure unit.

Due to the heat generated during the exposure step, the hydrophobic thermoplastic polymer particles may fuse or coagulate so as to form a hydrophobic phase which corresponds to the printing areas of the printing plate. Coagulation may result from heat-induced coalescence, softening or melting of the thermoplastic polymer particles. There is no specific upper limit to the coagulation temperature of the thermoplastic hydrophobic polymer particles, however the temperature should be sufficiently below the decomposition temperature of the polymer particles. Preferably the coagulation temperature is at least 10° C. below the temperature at which the decomposition of the polymer particles occurs. The coagulation temperature is preferably higher than 50° C., more preferably above 100° C.

### Development

Development, i.e., removal of the unexposed areas of the image-wise exposed precursor, is performed on-press. When the precursor has been exposed off-press in a plate-setter, the exposed precursor is mounted on the printing press. Preferably the development on-press is carried out as follows: while the print cylinder with the precursor mounted thereon rotates, the dampening form roller supplying the dampening liquid is dropped on the precursor, e.g., during 10 revolutions of the print cylinder, and subsequent thereto also the inking form rollers are dropped on the precursor. Generally, after about 100, more preferably after about 50 revolutions of the print cylinder, the first clear and useful prints are obtained, indicating the completion of the development. According to an alternative preferred embodiment, the inking form rollers and the dampening form roller may be dropped simultaneously or the inking form rollers may be dropped first.

With regard to the dampening liquids useful in the present invention, there is no particular limitation and commercially available dampening liquids, also known as fountain solutions, can be used in the recommended dilution. The dampening liquid may include isopropyl alcohol (IPA) or any known IPA-replacing compound.

Preferably, after the on-press development is completed, the ink is removed from the plate by printing with the inking form rollers disengaged, so called “sheeting off” of the ink. Alternatively, one may also stop the press and clean the plate manually with a plate cleaner. One may also make use of any possible “washing device” on the press that allows to clean the plate and remove the ink from its image areas during operation, while the ink and dampening form rollers are disengaged. Alternatively, after on-press development, the thus obtained plate is immediately baked while the ink may still be present on image-areas of the plate.

### Baking

In accordance with the present invention, the developed plate is subjected to a mild post-baking step during a baking period of two minutes or less, i.e., between 5 seconds and 2 minutes. Preferably the baking period is less than one minute, more preferably less than 30 seconds. During the baking step, the plate is heated up to a baking temperature which is higher than the glass transition temperature of the thermoplastic particles. A preferred baking temperature is above 50° C., more preferably above 100° C. ‘Baking temperature’ as used herein refers to the temperature of the plate during the baking process. In a preferred embodiment, the baking temperature does not exceed 300° C. during the baking period. More preferably, the baking temperature does not exceed 250° C., even not 220° C. Baking can be performed off-press in conventional hot air ovens or in ovens equipped with lamps emitting infrared light as disclosed in EP-A 1 506 854 but preferably, the baking step in the method according to the present invention is performed on-press. Any suitable heating means may be used but preferably, baking is carried out using lamps emitting infrared radiation or infrared lasers. A combination of UV and IR radiation may also be used in the baking step. For example, the heating means as described in EP-As 693 371 and 522 804 and DE 19 939 240 may also be used in the present invention.

The baking temperature can be measured, monitored and adjusted by means of one or more temperature probes, e.g., thermocouples, preferably fixed to the backside of the support. Since the coating is very thin (typically less than 1 μm) relative to the support, the temperature of the coating is essentially equal to the temperature of the support. Especially when using large plates, it may be observed that the temperature profile (temperature versus time) during the baking process at one spot on the plate, e.g., near the edge, is different from the temperature profile at another spot, e.g., near the center of the plate. In such case, it is preferred that the temperature at any spot on the plate, does not exceed a temperature of 300° C., more preferably a temperature of 250° C. and most preferably a temperature of 200° C.

Preferably, an exhaust which removes volatile compounds that may be released from the plate material is present in the present invention. The exhaust preferably includes an easily exchangeable filter.

After the baking step, the developed printing plate may be subjected to a cleaning step before starting to print. The cleaning step may be performed with plain water or preferably with commercially available plate cleaners.

### EXAMPLES

### Materials

styrene/acrylonitrile copolymer:weight ratio 60/40, stabilized with an anionic wetting agent; particle size of 41 nm, measured with a Brookhaven BI-90 analyzer, commercially available from Brookhaven Instrument Company, Holtsville, N.Y., USA.
IR dye, according to the following structure and disclosed in EP 1 736 312.

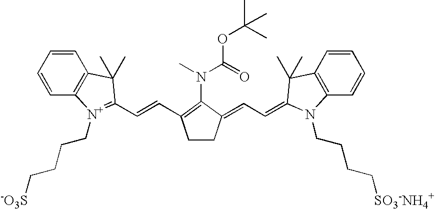

Aqualic AS58, a polyacrylic acid from Nippon Shokubai.
HEDP, 1-hydroxyethylidene-1,1-diphosphonic acid from Solutia.
ST-01, anti-oxidant.
Zonyl FSO 100, a perfluorinated surfactant from Dupont.

### Preparation of the Lithographic Support

A 0.3 mm thick aluminum foil was degreased by spraying with an aqueous solution containing 34 g/l of NaOH at 70° C. for 6 seconds and rinsed with demineralized water for 3.6 seconds. The foil was then electrochemically grained during 8 seconds using an alternating current in an aqueous solution containing 15 g/l of HCl, 15 g/l of SO₄²⁻ ions and 5 g/l of A1³⁺ ions at a temperature of 37° C. and a current density of about 100 A/dm² (charge density of about 800 C/dm²). Afterwards, the aluminum foil was desmutted by etching with an aqueous solution containing 145 g/l of sulphuric acid at 80° C. for 5 seconds and rinsed with demineralized water for 4 seconds. The foil was subsequently subjected to anodic oxidation during 10 seconds in an aqueous solution containing 145 g/l of sulphuric acid at a temperature of 57° C. and a current density of 33 A/dm² (charge density of 330 C/dm²), then washed with demineralized water for 7 seconds and post-treated for 4 seconds (by spray) with a solution containing 2.2 g/l of polyvinylphosphonic acid (PVPA) at 70° C., rinsed with demineralized water for 3.5 seconds and dried at 120° C. for 7 seconds. The support thus obtained is characterized by a surface roughness Ra of 0.35-0.4 μm (measured with interferometer NT1100) and have an anodic weight of about 4.0 g/m².

### Preparation of the Printing Plate Precursor

A printing plate precursor was produced by applying a coating onto the above described lithographic support. The aqueous coating solution had a pH of 3.55 and included the compounds listed in Table 1. After drying, the coating weight was 0.446 g/m².

TABLE 1
Composition of the dry coating

| INGREDIENTS | wt. % |
|---|---|
| Styrene/acrylonitrile copolymer | 71.75 |
| IR dye | 12.33 |
| Aqualic AS58 | 9.91 |
| HEDP | 2.69 |
| ST-01 | 2.24 |
| Zonyl FSO 100 | 1.12 |

### Preparation of the Printing Plates PP-01 to PP-03

The obtained printing plate precursors were exposed with a CREO Trendsetter (40 W) (plate-setter available from Creo, Burnaby, Canada), operating at an energy density of respectively 130 mJ/cm² (PP-01 and PP-03) and 210 mJ/cm² (PP-02) at 150 rpm (see Table 2).

The exposed PP-01 to PP-03 were mounted next to each other on the plate cylinder of a Ryobi 522 HX printing press equipped with a Rollin Elastostrip compressible blanket. The following ink/fountain combination was used: K+E 800 (black ink)/4% Hostmann-Steinberg Combifix XL. The following start-up procedure was used: first 10 revolutions with the dampening form rollers engaged, then 5 revolutions with both the dampening and ink form rollers engaged, then start printing. 100 Sheets were printed (80 g offset paper). This resulted in an effective clean-out of the non-image areas of all plates, as is evident from the fact that the plates showed no toning whatsoever on printed sheet 50. Subsequently, printing continued but with the ink form rollers disengaged, so as to remove the ink from the plates (so-called “sheeting off” of the ink). PP-03 was then taken off from the press and was baked. The baking step of PP-03 was carried out by passing this plate through a hot air baking oven, set at a temperature of 220° C., at a speed of 70 cm/min. The effective dwell-time of the plate in the baking oven was 60 seconds. After this baking step, PP-03 was remounted on the printing press and cleaned with mild plate cleaner Agfa G642b, available from Agfa Graphics NV.

TABLE 2
Exposure and baking of PP-01 to PP-03

| | exposure energy | Baking | Baking |
|---|---|---|---|
| Printing | density | temperature | dwell time |
| Plate | mJ/cm² | (° C.) | (s) |
| PP-01 (COMP) | 130 | — | — |
| PP-02 (COMP) | 210 | — | — |
| PP-03 (INV) | 130 | 220 | 60 |

Printing with Comparative PP-01 and PP-02 and Inventive PP-03

After PP-03 has been remounted on the press, the printing press was re-started, using the restart procedure as described above. Subsequently, 50,000 impressions were made on 80 g offset paper. The lithographic properties of the plates were determined by visual examination of the printed sheets after respectively 5,000 and 50,000 impressions. The quality of the image parts was determined by inspection of the rendering of a 1% dot patch (200 lpi) generated with the AGFA BALANCED SCREENING software (trademark of Agfa Graphics NV) on the printed sheet. A good rendering of this patch is considered a good criterium for the compatability of the printing plates with a high-resolution screening technology, such as Agfa CRISTALRASTER (trademark from Agfa Graphics NV), where microdots as small as 21 μm (2×2 pixels at 2400 dpi) are used.

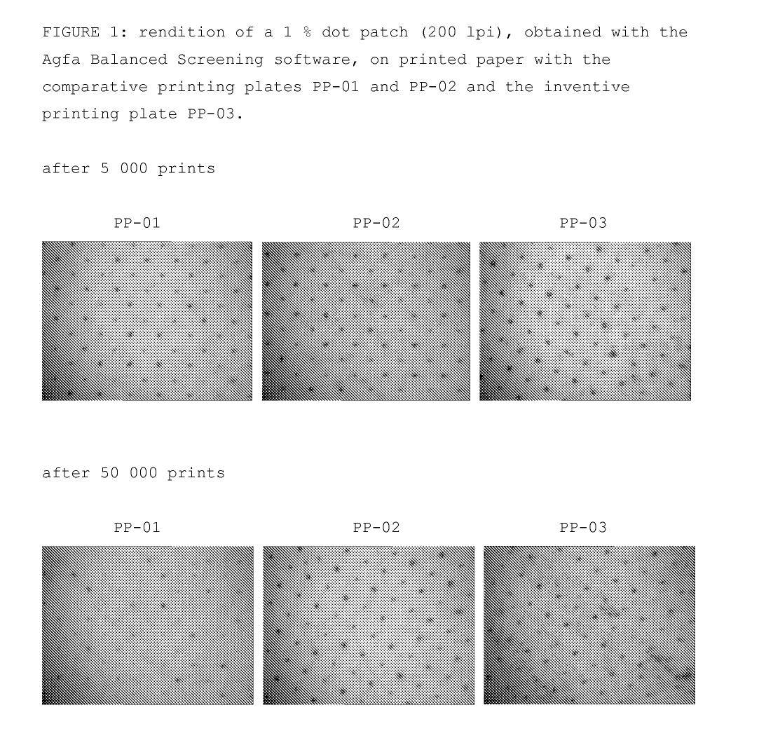

The results are presented in Table 3 and in FIG. 1: at an exposure density of 130 mJ/cm² or 210 mJ/cm² the rendering of the 1% dot patch (200 lpi) on the printed sheet after 5,000 impressions is similar for all three plates. Furthermore, the rendering of the 1% patch on the printed sheet after 50,000 impressions is similar for both the inventive PP-03, which has been underexposed but baked, and the comparative PP-02, which has been exposed at 210 mJ/cm². The rendering of the 1% patch on the printed sheet after 50,000 impressions for the comparative PP-01, which has been exposed at 130 mJ/cm² but not baked, is largely defective, since almost no dots are present anymore on the printed sheet. Thus, the mechanical and chemical resistance of the image areas exposed to an energy density of 130 mJ/cm² is largely insufficient to retain an acceptable quality during printing while the mild post-baking step—without prejudice to the scope of our claims—seems to compensate for the underexposure.

TABLE 3
Printing results

Rendition of a 1% dot patch
(200 lpi)on a printed sheet(1)

| | After 5,000 | After 50,000 |
|---|---|---|
| | impressions | impressions |
| PP-01 (COMP) | + | − |
| PP-02 (COMP) | + | + |
| PP-03 (INV) | + | + |

(1) +: indicates that the 1% @ 200 lpi ABS(Agfa Balanced Screening) patch on the printed sheet is unaffected. −: indicates that the 1% @ 200 lpi ABS(Agfa Balanced Screening) patch on the printed sheet is severely damaged.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-10. (canceled)

11. A method for making a lithographic printing plate comprising the steps of:
providing a lithographic printing plate precursor including a heat sensitive image-recording layer, the heat-sensitive image-recording layer including hydrophobic thermoplastic particles;
image wise exposing the precursor to infrared radiation having an energy density of 190 mJ/cm³ or less;
mounting the exposed precursor on a printing press;
developing the precursor by supplying ink and/or fountain solution to the precursor mounted on the printing press; and
baking the plate by keeping the plate at a temperature above the glass transition temperature of the hydrophobic thermoplastic particles for a period between 5 seconds and 2 minutes.

12. A method for making a lithographic printing plate comprising the steps of:
mounting a lithographic printing plate precursor on a printing press, the precursor including a heat sensitive image-recording layer, the heat sensitive image-recording layer including hydrophobic thermoplastic particles;
image-wise exposing the precursor to infrared radiation having an energy density of 190 mJ/cm³ or less;
developing the mounted precursor by supplying ink and/or fountain solution to the precursor mounted on the printing press; and
baking the plate by keeping the plate at a temperature above the glass transition temperature of the hydrophobic thermoplastic particles for a period between 5 seconds and 2 minutes.

13. The method according to claim 11, wherein the energy density is 130 mJ/cm² or less.

14. The method according to claim 12, wherein the energy density is 130 mJ/cm² or less.

15. The method according to claim 11, wherein the baking period is less than 30 seconds.

16. The method according to claim 12, wherein the baking period is less than 30 seconds.

17. The method according to claim 11, wherein the temperature of the plate does not exceed 250° C. during the baking period.

18. The method according to claim 12, wherein the temperature of the plate does not exceed 250° C. during the baking period.

19. The method according to claim 15, wherein the temperature of the plate does not exceed 250° C. during the baking period.

20. The method according to claim 16, wherein the temperature of the plate does not exceed 250° C. during the baking period.

21. The method according to claim 11, wherein after baking the plate, further comprising the step of:
cleaning the plate with a commercially available plate cleaner.

22. The method according to claim 11, wherein after development on the printing press and before baking, further comprising the step of:
removing ink from the plate.

23. The method according to claim 11, wherein the hydrophobic thermoplastic particles have an average particle diameter of from 25 nm to 55 nm.

24. The method according to claim 12, wherein the hydrophobic thermoplastic particles have an average particle diameter of from 25 nm to 55 nm.

25. The method according to claim 11, wherein an amount of the hydrophobic thermoplastic polymer particles is at least 70% by weight relative to a weight of all ingredients of the image-recording layer.

26. The method according to claim 23, wherein an amount of the hydrophobic thermoplastic polymer particles is at least 70% by weight relative to a weight of all ingredients of the image-recording layer.

27. A method of lithographic printing comprising the steps of:
making a lithographic printing plate according to claim 11;
supplying ink and fountain solution to the plate; and
transferring the ink to paper.

28. A method of lithographic printing comprising the steps of:
making a lithographic printing plate according to claim 12;
supplying ink and fountain solution to the plate; and
transferring the ink to paper.
